(19) United States
(12) Patent Application Publication
(10) Pub. No.: US 2006/0190787 A1
(43) Pub. Date: Aug. 24, 2006

(54) Target system, debugging system, integrated circuit device, microcomputer and electronic apparatus

(76) Inventor: Makoto Kudo, Fujimi (JP)

Correspondence Address: HARNESS, DICKEY & PIERCE, P.L.C., P.O. BOX 828, BLOOMFIELD HILLS, MI, 48303, US

(21) Appl. No.: 11/314,643

(22) Filed: Dec. 21, 2005

(30) Foreign Application Priority Data
Feb. 22, 2005 (JP) 2005-045356

(51) Int. Cl. G01R 31/28

(52) U.S. Cl. 714/731

(57) ABSTRACT

A debugging system that includes a debugging tool in a small pin count package and a target system that is a debugging object of the debugging tool, wherein the substrate of the target system includes an integrated circuit device with a built-in CPU and a communicator for generating and outputting a digital clock, and the integrated circuit device includes an internal debugging module having an on-chip debugging feature for conducting clock synchronous communication with the debugging tool in a small pin count package and a clock input terminal for inputting a clock necessary to conduct clock synchronous communication with the debugging tool in a small pin count package, and the substrate includes a clock output terminal that can be connected to the debugging tool in a small pin count package, wherein the digital clock signal that is outputted from the communicator is outputted outside via the clock output terminal placed on the substrate and is supplied to the inside of the integrated circuit device via the clock input terminal on the integrated circuit device, and the debugging tool in a small pin count package has a clock input terminal that is connected to the clock output terminal on the substrate with a communication line, via which a clock for synchronous communication that is outputted from the target system is received.

### BACKGROUND

1. Technical Field

The present invention relates to a target system, a debugging system, an integrated circuit device, a microcomputer and an electronic apparatus.

2. Related Art

In these years, demand for microcomputers that can perform sophisticated information processing, embedded in electronic apparatuses such as game consoles, car navigation systems, printers, personal digital assistances and the like, is growing. Such an embedded-type microcomputer is usually mounted on a user board that is called a target system. Meanwhile, a debugging tool (a software development support tool) in a small pin count package, such as an in-circuit emulator (ICE), is widely used for supporting the development of software to run the target system.

As such a kind of ICE, an ICE that is called a CPU switching ICE, as shown in FIG. 7, has become mainstream. With the CPU switching ICE, a microcomputer 302 is detached from a target system 300 during debugging and a probe 306 of a debugging tool 304 is connected thereto instead. The debugging tool 304 then emulates the operation of the detached microcomputer 302. The debugging tool 304 performs various processes that are necessary for debugging.

However, the CPU switching ICE has disadvantages in that the larger number of pins the probe 306 has, the larger number of lines 308 the probe 306 has. It makes it difficult to emulate the operation of the microcomputer 302 at high frequencies (by way of example, the limit is at around 33 MHz). It also makes it difficult to design the target system 300. Further, the operating environment of the target system 300 (such as signal timings or load conditions) changes between in an actual operation mode when the microcomputer 302 is mounted to run and in a debugging mode when the operation of the microcomputer 302 is emulated by the debugging tool 304. Moreover, the CPU switching ICE has other disadvantages in that a debugging tool with a different design and a probe that has a different number of pins on different positions has to be used when a different type of microcomputer is used, even if it is a modified version thereof.

Meanwhile, a known alternative to solve these disadvantages of the CPU switching ICE is an ICE in which pins and features for debugging are mounted on a mass production chip to provide the same features as the ICE. As such an ICE on which debugging features are mounted, a microcomputer that has an internal debugging module built in is known, the debugging module having on-chip debugging features for conducting clock synchronous communication with a debugging tool in a small pin count package (such as an ICE) and for performing a debugging command entered via the debugging tool.

In such a case, a microcomputer conducts debugging through clock synchronous communication with a debugging tool.

In such a case, there are needed, between a debugging tool and a microcomputer, a break input from the debugging tool to the microcomputer, a break/run input from the microcomputer to the debugging tool, data communication (such as a debugging command) from the debugging tool to the microcomputer, data communication from the microcomputer to the debugging tool, a synchronous clock for communication between the input debugging tool and the microcomputer, a plurality of pins for communicating additional information, such as a trace, from the microcomputer to the debugging tool and a terminal (pin), such as a groundline, between the input debugging tool and the microcomputer.

JP-A-8-255096 and JP-A-11-282719 are examples of related art.

Although the accumulated number of terminals (pins) for debugging keeps accordingly increasing, it is preferable that the number of terminals that are necessary only for debugging but are unnecessary for end users is kept as small as possible. The increase of the number of terminals (pins) in a microcomputer package leads to a cost increase of an IC and the like.

Further, the increase of the number of pins between a board and a debugging tool makes the board design more difficult, which lowers reliability and leads to a development cost increase and a prolonged development period for the board and the system.

### SUMMARY

An advantage of the invention is to provide a debugging system in which the number of unnecessary terminals for end users is kept as small as possible in a target system that has pins and features for debugging mounted on a mass production chip, a target system, an integrated circuit device and the like.

1. A first aspect of the invention is to provide a debugging system that includes a debugging tool in a small pin count package and a target system, which is a debugging object of the debugging tool. The substrate of the target system includes an integrated circuit device with a built-in CPU and a communicator for generating and outputting a digital clock. The integrated circuit device includes an internal debugging module having an on-chip debugging feature for conducting clock synchronous communication with the debugging tool in a small pin count package, and a clock input terminal for inputting a clock necessary to conduct clock synchronous communication with the debugging tool in a small pin count package. The substrate includes a clock output terminal that can be connected to the debugging tool in a small pin count package. The digital clock signal that is outputted from the communicator is outputted outside via the clock output terminal placed on the substrate, and is supplied to the inside of the integrated circuit device via the clock input terminal on the integrated circuit device. The debugging tool in a small pin count package has a clock input terminal that is connected to the clock output terminal on the substrate with a communication line, via which a clock for synchronous communication that is outputted from the target system is received.

The substrate here implies a user board, a print substrate and the like. In addition to an integrated circuit device with a built-in CPU (such as a microcomputer), other kinds of integrated circuit devices, such as a memory and the like, can also be mounted on the substrate. An example of a debugging tool in a small pin count package is an ICE in a small pin count package.

During debugging, the clock output terminal placed on the substrate is connected to the debugging tool in a small pin count package (such as an ICE), which receives a clock for synchronous communication from the target system.

Because the output of the communicator is connected to the clock output terminal as well as the clock input terminal on the integrated circuit device, a clock for synchronization is provided both to the integrated circuit device and the debugging tool in a small pin count package, which makes it possible to perform clock synchronous communication.

According to the first aspect of the invention, it is sufficient if there is a terminal for clock input, on the integrated circuit device, as clock-related terminals, which are necessary for synchronous communication during debugging, because the integrated circuit device inputs a digital clock from a communicator that is mounted on the substrate.

Although a terminal for analog input and a terminal for clock output are needed, for example, in the case where the integrated circuit device is configured so that analog input is received from a transmit terminal on a substrate to output a clock that is internally generated based on the analog input, it is enough, according instead to the first aspect of the invention, to have a terminal for clock input and a terminal for clock output is not needed.

In this way, according to the first aspect of the invention, the number of terminals (pins) that are used only in a debugging mode but are not used in a user mode (in a user program) can be reduced on an integrated circuit device with a built-in CPU, which can prevent the cost increase of an integrated circuit device.

2. Further, in the debugging system according to the first aspect of the invention, the substrate of the target system and the debugging tool in a small pin count package are grounded.

The substrate can be grounded directly or can be grounded also indirectly via an outlet or the like.

By doing so, the groundline for connecting the substrate of the target system and the debugging tool in a small pin count package can be omitted, which reduces the number of pins on the substrate.

3. A second aspect of the invention is to provide a target system in which an integrated circuit device with a built-in CPU is mounted on a substrate. A communicator for generating and outputting a digital clock is mounted on the substrate. The integrated circuit device includes an internal debugging module having an on-chip debugging feature for conducting clock synchronous communication with a debugging tool in a small pin count package, and a clock input terminal for inputting a clock necessary to conduct clock synchronous communication with the debugging tool in a small pin count package. The substrate includes a clock output terminal that can be connected to the debugging tool in a small pin count package. The digital clock signal that is outputted from the communicator is outputted outside via the clock output terminal placed on the substrate and is supplied to the inside of the integrated circuit device via the clock input terminal on the integrated circuit device.

4. Further, in the target system according to the second aspect of the invention, the substrate is grounded.

5. A third aspect of the invention is to provide an integrated circuit device according to any of the aspects described above.

6. A fourth aspect of the invention is to provide a microcomputer that includes an integrated circuit device according to any of the aspects described above.

7. A fifth aspect of the invention is to provide an electronic apparatus that includes a microcomputer according to the above-described aspect, an input source for data that is processed by the microcomputer, and an output device for outputting data that is processed by the microcomputer.

### BRIEF DESCRIPTION OF THE DRAWINGS

The invention will be described with reference to the accompanying drawings, wherein like numbers reference like elements.

FIG. 1 is a diagram showing a configuration of a target system, a debugging system and a microcomputer according to the embodiment of the invention.

FIG. 2 is a diagram showing a configuration of a target system, a debugging system and a microcomputer of a comparative example.

FIG. 3 is a diagram showing another configuration of a target system, a debugging system and a microcomputer according to the embodiment of the invention.

FIG. 4 is an example of a hardware block diagram of a microcomputer according to the embodiment of the invention.

FIG. 5 is an example of a block diagram of an electronic apparatus that includes a microcomputer.

FIGS. 6A, 6B and 6C are examples of outline views of various electronic apparatuses.

FIG. 7 is an example of an ICE that is called a CPU switching type.

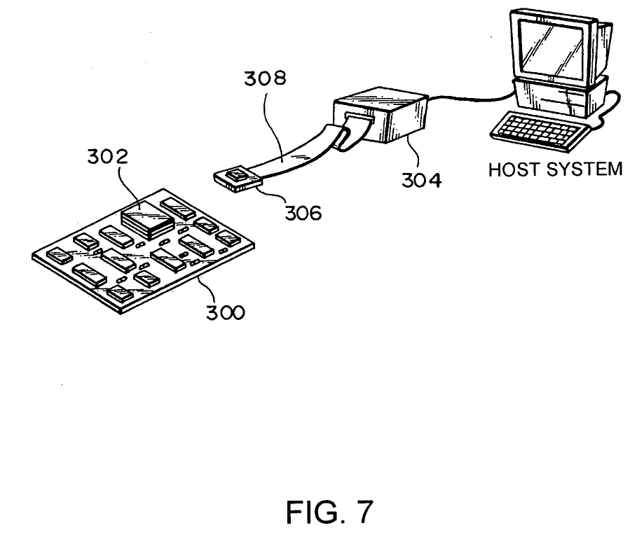

### DESCRIPTION OF EXEMPLARY EMBODIMENTS

A preferred embodiment of the invention will now be described in detail with reference to the drawings.

1. Characteristics of the Present Embodiment

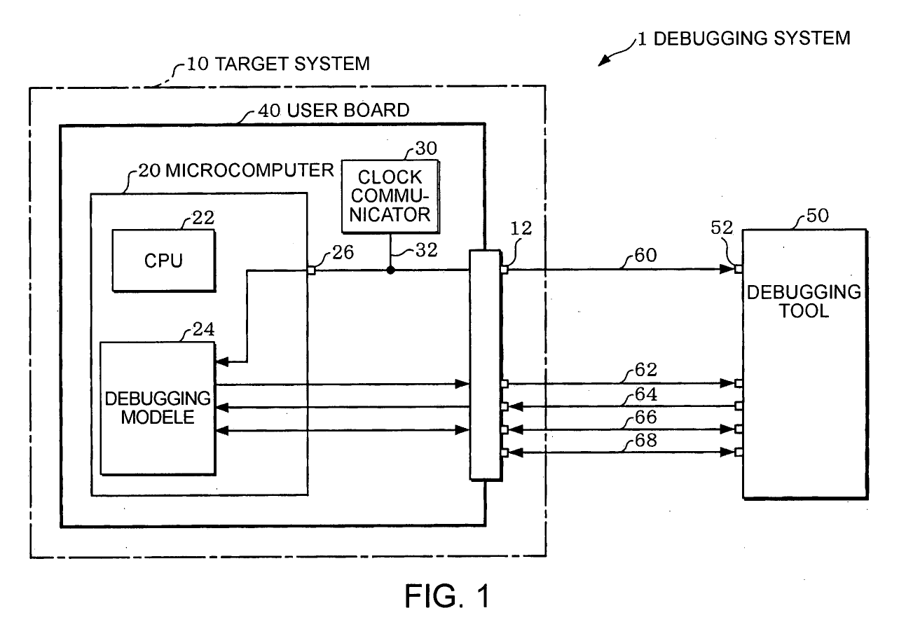

FIG. 1 is a diagram for describing a configuration of a target system, a debugging system and a microcomputer according to the embodiment.

A debugging system 1 according to the embodiment includes a debugging tool in a small pin count package (such as an ICE) 50 and a target system 10 that is a debugging object of the debugging tool.

In the target system 10, a microcomputer (an example of an integrated circuit device with a built-in CPU) 20 is mounted on a substrate (user board) 40. Semiconductor integrated circuit devices, such as a memory, can be mounted on the substrate (user board) 40, in addition to the microcomputer 20.

On the substrate (user board), a communicator (clock communicator) 30 for generating and outputting a digital clock is mounted. The communicator (clock communicator) 30 is provided, for example, with a crystal oscillator or the like.

The microcomputer 20 includes an internal debugging module 24 having an on-chip debugging feature for conducting clock synchronous communication with the debugging tool in a small pin count package (such as an ICE) 50 and for performing a debugging command entered from the debugging tool.

The microcomputer, in addition, includes a CPU 22.

The CPU 22 includes an internal resistor and performs various kinds of instructions. The internal resistor includes general registers R0 to R15, an SP (stack pointer register), which is a special register, an AHR (arithmetic operation high register), an ALR (arithmetic operation low register) and the like. The CPU 22 performs a user program in a user mode and performs a monitor program or a debugging command in a debug mode.

The debugging module 24 includes a ROM, a RAM, a control register, an SIO and the like and performs various kinds of instructions (such as an I/O interface with the debugging module, an analysis of a debugging command, an intervention process from a user program to a monitor program and the like) that are necessary for the CPU 22 to perform a monitor program or a debugging command in a debug mode.

A monitor program is stored in the ROM of the debugging module 24. The content of the internal resistor on the CPU 22 is evacuated into the RAM on the transition to a debug mode (when a break occurs in a user program). Thus, the operation of the user program can be appropriately restarted after the debug mode. Further, the read of the content of the internal resistor and the like can be carried out with a command or the like of the monitor program.

The control register is a register for controlling various kinds of debugging processes and includes, for example, a stepwise execution enabling bit, a break enable bit, a break address bit, a trace enable bit and the like. Various kinds of debugging processes are carried out by the CPU 22 driven by the monitor program, writing data to each bit of the control register and reading data of each bit.

The SIO controls debugging data that is sent and received between with the debugging tool 50 placed outside of the microcomputer 20.

The microcomputer 20 further includes a clock input terminal 26 for inputting a clock that is necessary to conduct clock synchronous communication with the debugging tool in a small pin count package (such as an ICE) 50.

The substrate (user board) 40 has an external terminal 12 that can be connected to the external debugging tool in a small pin count package 50.

The output from the communicator 30 is connected to the clock input terminal 26 of the microcomputer 20 and the input of the external terminal 12 on the substrate. Here, the digital clock signal 32 outputted from the communicator 30 is outputted outside via the external clock output terminal 12 that is placed on the substrate and is provided to the inside of the microcomputer 20 via the clock input terminal 26.

The debugging tool in a small pin count package (such as an ICE) 50 has an external clock input terminal 52. The external clock input terminal 52 and the external clock output terminal 12 on the substrate (user board) 40 are connected to each other via a communication line 60. The debugging tool in a small pin count package receives a clock for synchronous communication, which is outputted from the target system, via the communication line 60.

The debugging tool in a small pin count package sends a debugging command and sends and receives data through a clock synchronous communication with the microcomputer according to the clock received from the substrate (user board) 40.

The number 62 refers to a communication line that sends data and the like from the debugging module 24 to the debugging tool 50. The number 64 refers to a communication line that sends data and the like (including a debugging command) from the debugging tool 50 to the debugging module 24. The number 66 refers to a communication line for exchanging debug signals (including a stop/start signal for a trace, a break signal and the like) through two-way communication between the debugging tool 50 and the debugging module 24.

The number 68 refers to a groundline for connecting the substrate (user board) 40 and the debugging tool 50.

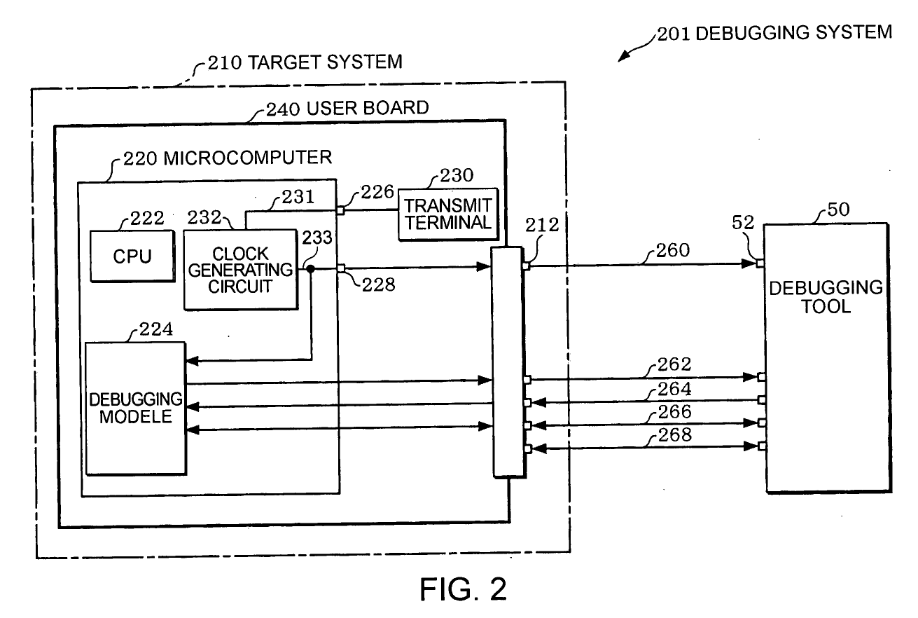

FIG. 2 is a diagram for describing a configuration of a target system, a debugging system and a microcomputer of a comparative example.

The debugging system 201 of a comparative example includes a debugging tool in a small pin count package (such as an ICE) 250 and a target system 210 that is a debugging object of the debugging tool 250.

In the target system 210 of the comparative example, a microcomputer 220, a transmit terminal (such as a crystal oscillator) 230 for generating and outputting an analog signal, and the like are mounted on the substrate (user board) 240.

The microcomputer 220 includes an input terminal 226 for inputting an analog signal that is necessary to generate a clock necessary for conducting clock synchronous communication with the debugging tool in a small pin count package (such as an ICE) 250, a clock generating circuit 232 for generating a clock based on the inputted analog signal, and an output terminal 228 for outputting outside the clock that is generated on the clock generating circuit 232.

The substrate (user board) 240 includes an external terminal 212 that can be connected to the external debugging tool in a small pin count package 250. The input of the external terminal 212 is connected to the output terminal 228 and outputs the clock that is outputted from the output terminal 228 via the external terminal 212 to a communication line 260.

In the comparative example, two terminals are needed for the microcomputer 220 of the target system 210, the one being a clock input terminal 226 and the other being a clock output terminal 228.

In the meanwhile, the microcomputer 20 of the target system 10 of the embodiment, as shown in FIG. 1, does not include, as a terminal for synchronous communication for debugging, a clock output terminal for outputting a clock to the outside. It is enough if there is a single terminal, which is the clock input terminal 26. In this way, the number of terminals (pins) that are necessary only for debugging can be reduced in the embodiment, which can prevent the cost increase of an integrated circuit device (microcomputer).

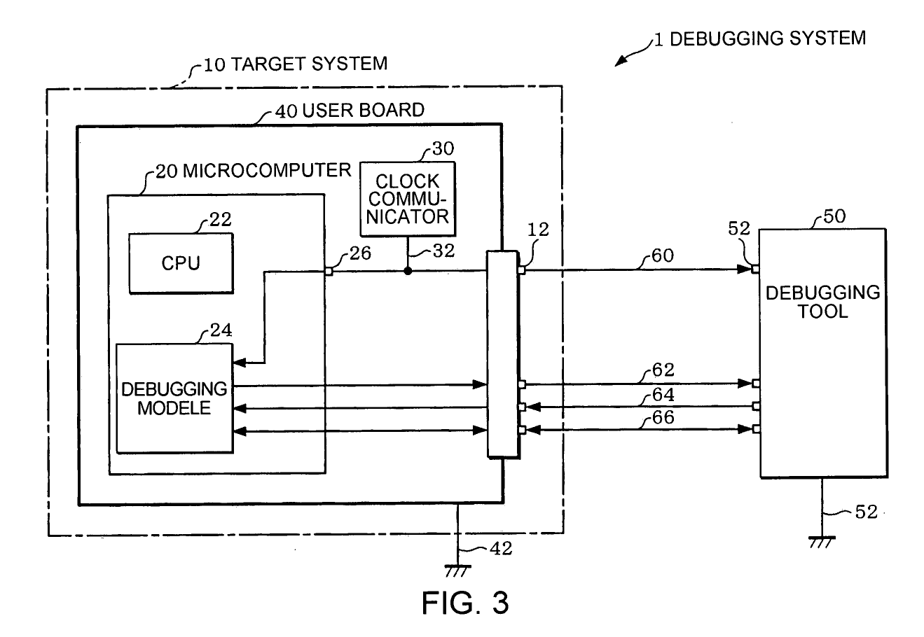

FIG. 3 is a diagram for describing another configuration of a target system, a debugging system and a microcomputer according to an embodiment of the invention.

Explanations are not given for the parts, in FIG. 3, that have the same numbers with those in FIG. 1, as they work just in the same way as in FIG. 1.

In the embodiment in FIG. 3, there is not a groundline 68 as in FIG. 1. Instead, the substrate (user board) 40 of the target system 10 and the debugging tool in a small pin count package 50 are grounded (refer to 42 and 52).

Here, the substrate (user board) 40 and the debugging tool 50 can be grounded directly or can be grounded also indirectly via an outlet or the like.

By doing so, the groundline for connecting the substrate (user board) 40 of the target system 10 and the debugging tool in a small pin count package 50 can be omitted, which can reduce the number of pins on the substrate (user board) 40.

2. Microcomputer

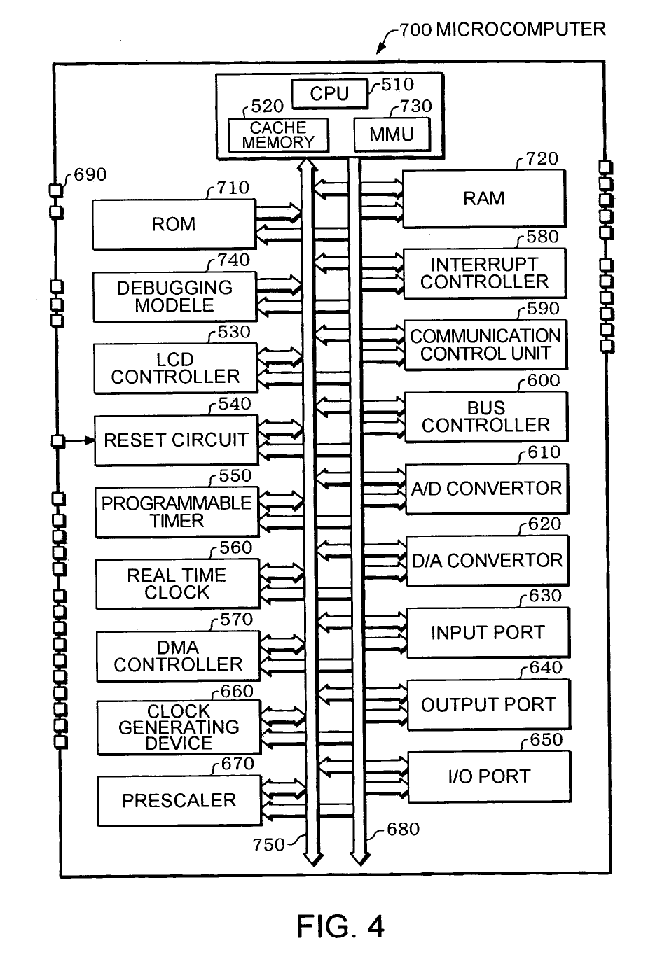

FIG. 4 is an example of a hardware block diagram of a microcomputer according to the embodiment.

The microcomputer 700 includes a CPU 510, a cache memory 520, a RAM 710, a ROM 720, an MMU 730, an LCD controller 530, a reset circuit 540, a programmable timer 550, a real time clock (RTC) 560, a DRAM controller 570, an interrupt controller 580, a communication control unit (serial interface) 590, a bus controller 600, an A/D converter 610, a D/A converter 620, an input port 630, an output port 640, an I/O port 650, a clock generating device 660, a prescaler 670 and a general bus 680 for connecting them, a debugging module 740, a dedicated bus 750 and the like, and various kinds of pins 690.

3. Electronic Apparatus

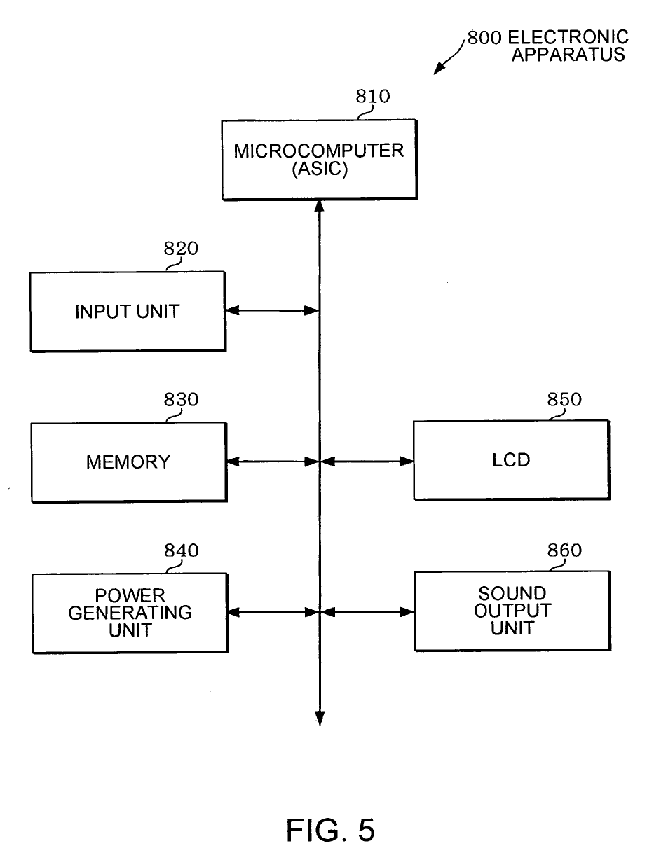

FIG. 5 is an example of a block diagram of an electronic apparatus according to the embodiment. The electronic apparatus 800 includes a microcomputer (or an ASIC) 810, an input unit 820, a memory 830, a power generating unit 840, an LCD 850 and a sound output unit 860.

Here, the input unit 820 is for inputting various kinds of data. The microcomputer 810 performs various kinds of processing based on the data that is inputted from the input unit 820. The memory 830 works as a working area for the microcomputer 810 and the like. The power generating unit 840 is for generating various kinds of power sources that are used by the electronic apparatus 800. The LCD 850 is for outputting various kinds of images (such as characters, icons, graphics and the like) that the electronic apparatus displays. The sound output unit 860 is for outputting various kinds of sounds (such as voices, game sounds and the like) that the electronic apparatus 800 outputs, the feature being carried out by hardware, such as a speaker.

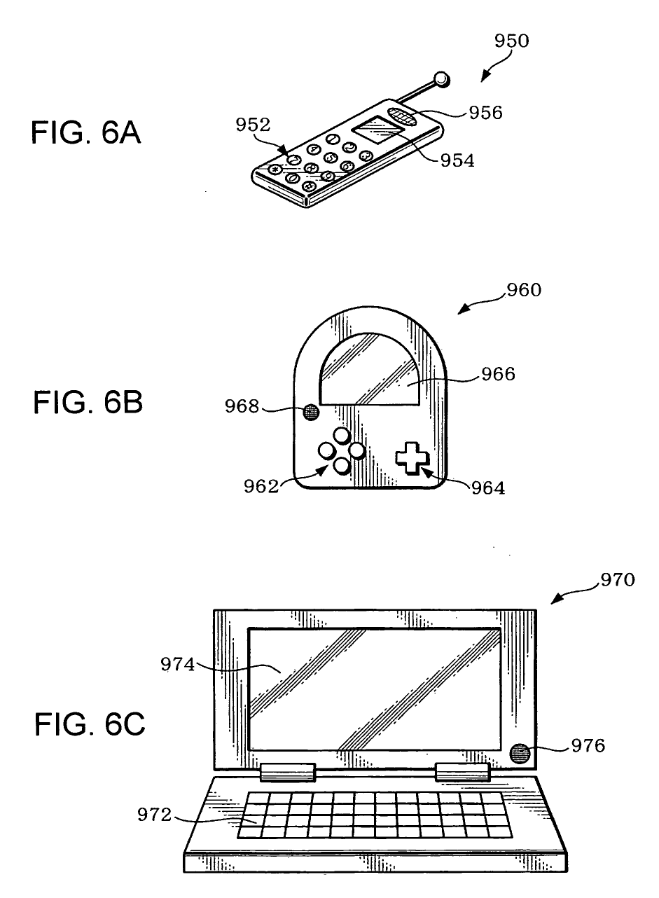

FIG. 6A shows an outline view of a cellular phone 950, which is an example of an electronic apparatus. The cellular phone 950 includes dial buttons 952 that work as an input unit, an LCD 954 that displays phone numbers, names, icons and the like, and a speaker 956 that works as a sound output unit for outputting voices.

FIG. 6B shows an outline view of a portable game console 960, which is an example of an electronic apparatus. The portable game console 960 includes a control button 962 that works as an input unit, a cross key 964, an LCD 966 that displays game images, and a speaker 968 that works as an output unit for outputting game sounds.

FIG. 6C shows an outline view of a personal computer 970, which is an example of an electronic apparatus. The personal computer 970 includes a keyboard 972 that works as an input unit, an LCD 974 that displays characters, icons, graphics and the like, and a sound output unit 976.

By embedding a microcomputer according to the embodiment into the electronic apparatuses in Figs. A, B and C, a rapid image processing and highly cost-effective electronic apparatus can be provided at a low cost.

Examples of electronic apparatuses that can adopt the embodiment include, in addition to those shown in FIGS. 6A, 6B and 6C, various kinds of electronic apparatuses having an LCD, such as personal digital assistances, pagers, electronic desk calculators, devices with a touch panel, projectors, word processors, video tape recorders (viewfinder types or monitor types), car navigation systems and the like.

The invention is not limited to the above-referenced embodiment. Any modified embodiment may be acceptable as long as the purpose of the invention can be achieved.

What is claimed is:

1. A debugging system, comprising:
a debugging tool in a small pin count package; and
a target system that is a debugging object of the debugging tool;
wherein the substrate of the target system includes an integrated circuit device with a built-in CPU and a communicator for generating and outputting a digital clock, and the integrated circuit device includes an internal debugging module having an on-chip debugging feature for conducting clock synchronous communication with the debugging tool in a small pin count package and a clock input terminal for inputting a clock necessary to conduct clock synchronous communication with the debugging tool in a small pin count package, and the substrate includes a clock output terminal that can be connected to the debugging tool in a small pin count package, wherein the digital clock signal that is outputted from the communicator is outputted outside via the clock output terminal placed on the substrate and is supplied to the inside of the integrated circuit device via the clock input terminal on the integrated circuit device, and the debugging tool in a small pin count package has a clock input terminal that is connected to the clock output terminal on the substrate with a communication line, via which a clock for synchronous communication that is outputted from the target system is received.

2. The debugging system according to claim 1, wherein the substrate on the target system and the debugging tool in a small pin count package are grounded.

3. A target system, comprising:
an integrated circuit device with a built-in CPU that is mounted on a substrate; and
a communicator for generating and outputting a digital clock that is mounted on the substrate, wherein the integrated circuit device includes an internal debugging module having an on-chip debugging feature for conducting clock synchronous communication with a debugging tool in a small pin count package, and a clock input terminal for inputting a clock necessary to conduct clock synchronous communication with the debugging tool in a small pin count package, and the substrate includes a clock output terminal that can be connected to the debugging tool in a small pin count package, wherein the digital clock signal that is outputted from the communicator is outputted outside via the clock output terminal placed on the substrate and is supplied to the inside of the integrated circuit device via the clock input terminal on the integrated circuit device.

4. The target system according to claim 3, wherein the substrate is grounded.

5. An integrated circuit device according to claim 1.

6. A microcomputer comprising an integrated circuit device according to claim 1.

7. An electronic apparatus comprising a microcomputer according to claim 6, an input source for data that is processed by the microcomputer, and an output device for outputting data that is processed by the microcomputer.
